(19) United States
(12) Patent Application Publication
(10) Pub. No.: US 2025/0176152 A1
(43) Pub. Date: May 29, 2025

(54) Systems, Methods, and Devices for a Wordline or a Bitline Formed and Disposed Within a Backside Metal Layer

(71) Applicant: Arm Limted, Cambridge (GB)

(72) Inventors: Andy Wangkun Chen, Austin, TX (US); Yew Keong Chong, Austin, TX (US); Sriram Thyagarajan, Austin, TX (US); Vivek Asthana, Greater Noida (IN)

(21) Appl. No.: 18/518,795

(22) Filed: Nov. 24, 2023

(51) Int. Cl. H10B 10/00; G11C 11/418

(52) U.S. Cl. CPC H10B 10/12; G11C 11/418; H10B 10/18

(57) ABSTRACT

According to one implementation of the present disclosure, an integrated circuit comprises: a memory macro unit including: one or more bitcells of one or more bitcell arrays, where a wordline or a bitline is at least partially disposed within a backside metal layer of the memory macro unit. In one implementation, a method comprises: transmitting, by a first wire of wiring, one or more control signals, where the first wire is disposed at least partially within a back-side metal layer. In one implementation, an integrated circuit comprises: a wire configured to transmit one or more control signals, where the wire is disposed at least partially on a back-side metal layer.

### I. FIELD

The present disclosure is generally related to the systems, methods, and devices for a wordline or a bitline at least partially formed and disposed within a backside metal layer.

### II. DESCRIPTION OF RELATED ART

Advances in technology have resulted in smaller and more powerful computing devices. For example, a variety of personal computing devices, including wireless telephones, such as mobile and smart phones, gaming consoles, tablets and laptop computers are small, lightweight, and easily carried by users. These devices can communicate voice and data packets over wireless networks. Further, many such devices incorporate additional functionality, such as a digital still camera, a digital video camera, a digital recorder, and an audio file player. Also, such devices can process executable instructions, including software applications, such as a web browser application, that can be used to access the Internet. As such, these devices can include significant computing and networking capabilities. For such devices, there is an ever-increasing demand for greater area efficiency for memory storage capacity and read/write capabilities.

Currently, memory design deficiencies can arise when implementing multiple wordline schemes and techniques to improve speed and performance in common memory applications. For instance, different metal layers can be used to provide different wordlines or bitlines along with multiple power rails; however, such memory designs examples can increase area and slow performance due to multiple additional layers formed on a substate. Also, additional metal added on the frontside layers can reduce memory speed due to added capacitance from additional conductive layers formed to overlay each other. Hence, there exists a need for a more efficient bitcell design that seeks to reduce area inefficiencies, improve integration schemes, and enhance speed and performance by providing more effective wordline and bitline design schemes and techniques for memory based applications.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a schematic diagram of a portion of an example integrated circuit in accordance with various implementations described herein.

FIG. 2 is a schematic diagram of a portion of an example integrated circuit in accordance with various implementations described herein.

FIG. 3 is a schematic diagram of a portion of an example integrated circuit in accordance with various implementations described herein.

FIG. 4 is a schematic diagram of a portion of an example integrated circuit in accordance with various implementations described herein.

FIG. 5 is an operation method in accordance with various implementations described herein.

FIG. 6 is an operation method in accordance with various implementations described herein.

FIG. 7 is a method in accordance with various implementations described herein.

FIG. 8 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

According to one implementation of the present disclosure, an integrated circuit comprises: a memory macro unit including: one or more bitcells of one or more bitcell arrays, where a wordline or a bitline is at least partially disposed within a backside metal layer of the memory macro unit. In certain implementations, the backside metal layer, for at least certain portions, is formed as the wordline or the bitline.

According to one implementation, a method comprises: transmitting, by a first wire of wiring, one or more control signals, where the first wire is disposed at least partially within a back-side metal layer. In certain implementations, the backside metal layer, for at least certain portions, is formed as the wire.

According to one implementation, an integrated circuit comprises: a wire configured to transmit one or more control signals, where the wire is disposed at least partially on a back-side metal layer. In certain implementations, the backside metal layer, for at least certain portions, is formed as the wire.

According to one implementation, an integrated circuit comprising: a memory macro unit comprising: one or more bitcells of one or more bitcell arrays, where at least a partial portion of a backside metal layer of the memory macro unit is formed as a wordline or a bitline.

According to one implementation, an integrated circuit comprising: a memory macro unit comprising: one or more bitcells of one or more bitcell arrays, where at least a partial portion of a backside metal layer of the memory macro unit is (and corresponds to) a wordline or a bitline. In certain aspects, the wordline or the bitline may be formed from the backside metal layer.

In current designs, certain multiport memory (e.g., 2-read, 1-write memory) have “too great” of a wordline resistance-capacitance (RC). Such high levels of wordline RC can create a relatively significant RC delay for a memory (e.g., a large SRAM memory). Advantageously, in certain inventive aspects, by utilizing both frontside and backside metals for wordlines, significant CPU performance and memory timing improvements may be realized.

In addition, in current designs, due to high levels of bitline RC, high density memory has a limitation of less than or equal to 256 rows per bitline in memory design. Advantageously, in certain inventive aspects, by utilizing both frontside and backside metals for bitlines, the bitline range can be doubled and extended to 512 rows per bitline. Accordingly, area, power, and timing improvements for L2-Data and L3-Data, for example, may be realized.

In various implementations, as described herein, advantageously, inventive systems, devices, and method can incorporate a backside metal layer (i.e., buried metal layer) to transmit control signals on wiring (either a bitline or a wordline) in memory design architecture.

In certain schemes and techniques, as described herein, the inventive methods support memory compiler graphical user interfaces (GUI) to generate memory instances (i.e., macros) with wire (e.g., bitline, wordline, or power line) disposition (e.g., placement) capability. Moreover, a tiling engine of the memory compiler can support stitching such memory instances together to allow wire disposition with minimized area penalty. In various implementations, an area “keep out zone” may be included as a surrounding perimeter for wire placement. Advantageously, such keep out zones may overlap over whitespaces within both frontside and backside of a memory macro. Hence, a higher area utilization may be realized at the system-on-chip (SoC) level. In various examples, the inventive circuits, systems, and methods can be utilized for wire configuration within macros for cache memory and/or main processor memory in SRAM, DRAM, and other memory such as read-only memory (ROM), non-volatile memory (NVM), CAM, or register files.

Certain definitions have been provided herein for reference. The term “macro” and “instance” have been utilized interchangeably—as in what is delivered from a memory compiler. A “macro” may have “butterfly architecture” (but not required), may be split into “banks”, “column-multiplexing”, and/or various other design features (e.g., power gating, redundancy, write mask) as per the decisions of a macro unit's (e.g., SRAM's) “architecture”. An “instance” or “macro” may be “single-banked” or “multi-banked”. Also, each bank is a nearly complete subset of the memory instance. And a large instance may be broken down into “smaller chunks” (each with separate control, word-line drivers, bit-cell array, input/output) for substantially performance and power reasons. For a particular “architecture”, the “instance” can have varying number of rows, columns, and banks to achieve the desired capacity. Multiple “instances” can be stitched together to implement a cache at a system-on-chip (SoC) level. Column multiplexers (or column mux) may be as part of input/output (I/O) circuitry, and the I/O circuitry includes several other blocks, including, but not limited to: sense amplifier, write driver, and precharge devices. In addition, a wire or wiring (e.g., a set of wires): e.g., can be a strip of polysilicon (for wordline); a metal (for bitline) or a diffusion region (used in transistor formation).

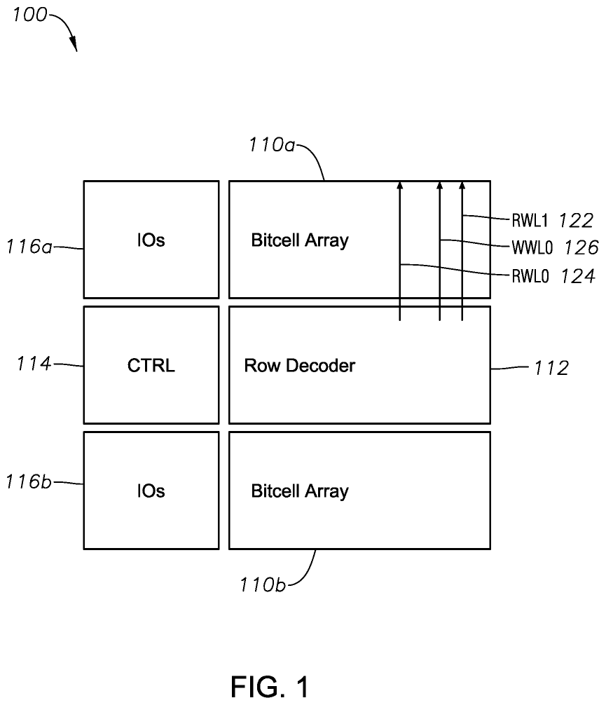

Referring to FIG. 1, an example portion of an integrated circuit 100 (e.g., a portion of a system-on-chip (SoC)) is shown. As illustrated, in certain implementations, the integrated circuit may include a memory macro unit 100 (e.g., including core array structure (e.g., a two-read one-write (2R1 W) multi-port (e.g., 3-port) memory using backside and frontside metal layers for wordlines). The memory macro unit 100 may include one or more bitcells of one or more bitcell arrays 110 (e.g., 110a, 110b) (i.e., memory instances, core arrays, memory arrays) (e.g., multi-port memory array); one or more word-line decoder blocks 112 (i.e., row decoders); and respective input/output (I/O) circuitry 116a, 116b for each of the one or more bitcell arrays 110. In various implementations, each of the I/O blocks 116a, 116b may include (not shown): sense amplifier circuitry, a pre-charge circuit, a column multiplexer, and input and output latches. In certain implementations, the one or more bitcell arrays 110 may be coupled to the one or more word-line decoder blocks 112. In certain implementations, the control circuitry 114 may be coupled to the one or more word-line decoder blocks 112, the respective input/output (I/O) circuitry 116a, 116b, and the one or more bitcell arrays 110.

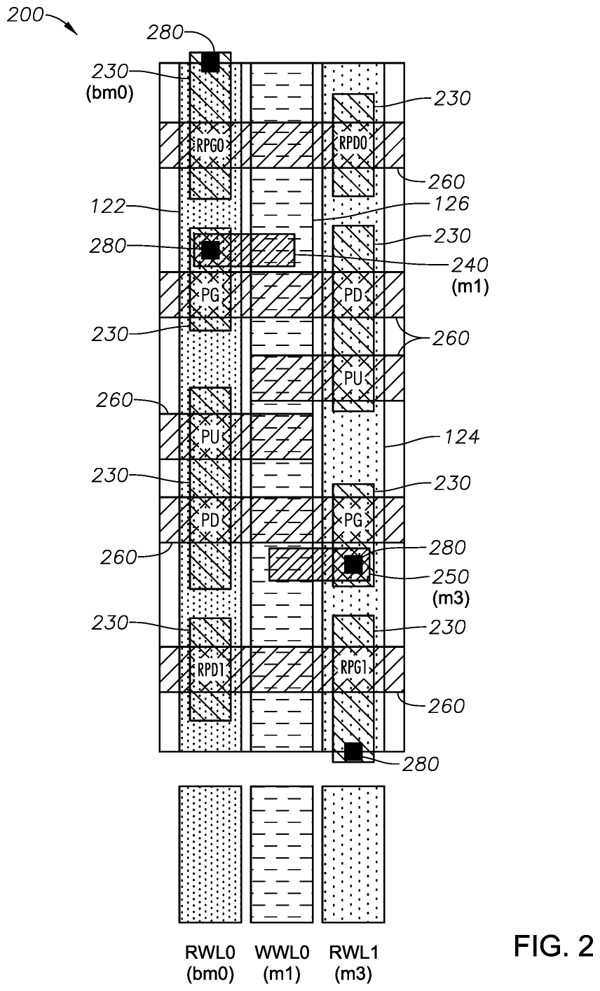

Also, in FIG. 1, first, second, and third wires 122, 124, 126 are shown. In one implementation: the first wire (RWL0) 122 is a first read wordline, the second wire (WWL0) 124 is a second read wordline, and a third wire (WWL0) 126 is a write wordline. In one example of such an implementation, the first wire 122 (i.e., the first read wordline) may be configured to be at least partially formed and positioned within (e.g., in certain cases: on, inside) a backside metal layer (i.e., buried metal layer) (as shown in greater detail in FIG. 2) as well the one or more bitcell arrays 110. In one example, the second wire 122 (i.e., the second read wordline) may be at least partially formed and positioned on a first frontside metal layer (e.g., M3 layer) as well the one or more bitcell arrays 110, and third wire 124 (i.e., a write wordline) may be at least partially formed and positioned on a second frontside metal layer (e.g., M1 layer) as well the one or more bitcell arrays 110.

Advantageously, such a disposition, according to inventive aspects, utilizes both frontside and backside metal layers. In doing so, in one example, a 2R1 W (e.g., 3 wordline) design may be implemented optimizing for better IPC performance. For instance, central processing unit (CPU) performance may be improved by approximately 0.5% IPC and memory timing may be improved by approximately 5-10%. In other examples, in different implementations (as per design preferences and requirements), the first and second read wordlines 122, 124 and write wordline 126 may be formed and positioned in any different combination on or within a backside metal layer and various two different frontside metal layers (e.g., M0-M7), respectively. Advantageously, in certain implementations, by designing for metal layers closest to the bitcell array(s), both frontside and backside metal layers, significant performance gains may be realized.

In certain implementations, the control circuitry (CTRL) 114 may be configured to enable one or more critical signals on wiring (e.g., wordline) to control (e.g., activate: “turn on/turn off”, activation of cells based on address input during both read and write operations) the one or more bitcell arrays 110a, 110b. In various examples, as described herein, a first wire of the wiring may be formed and disposed at least partially on or within a backside metal layer (or a buried metal layer) (e.g., BM0). As may be appreciated, in the various implmentations as described herein, the critical control signals may be one or more data input signals (i.e., data input) (DB) or one or more write enable signals (WEN). Also, in certain implementations, the control circuitry (CTRL) 114 may include a ground rail or line (VSS) (not shown) that is coupled to the one or more bitcell arrays 110.

In certain implementations, one or more through silicon vias (TSVs) 280 may be positioned through the memory macro unit 100, 200. In certain implementations, the one or more TSVs may intersect the memory macro unit 100, 200 in a substantially perpendicular orientation (i.e., direction) to extend, in certain cases, vertically through a 3D memory stack. In certain aspects, the TSVs may be utilized by the SoC for the transferrance of the control signals routed through the frontside and backside metals and bitcells arrays of the memory macro unit.

Referring to FIG. 2, an example portion of an integrated circuit 200 (e.g., memory macro unit) corresponding to the integrated circuit 100 in FIG. 1 is shown. As illustrated, the integrated circuit 200 depicts the frontside and backside metal layers, first and second read wordlines, and write wordline shown within the example portion of the two-read one-write (2R1 W) multi-port (e.g., 3-port) memory.

As illustrated, each wiring is shown to be at least partially disposed on or within different metal layers (e.g., metal levels). For instance, the first read wordline (RWL0) 122 may be proximate to and/or partially disposed within and/or upon a backside metal layer (e.g., bm0) 230 (e.g., formed within a substrate) as well as to the one or more bitcell arrays 110a, 110b (not shown). Likewise, the write wordline (WWL0) 126 may be proximate to and/or partially disposed within and/or upon a first frontside metal layer (e.g., M1 layer) 240 as well as to the one or more bitcell arrays 110a, 110b (not shown). Also, the second read wordline (RWL1) 124 may be proximate to and/or partially disposed within and/or upon a second frontside metal layer (e.g., M3 layer) as well as to the one or more bitcell arrays 110a, 110b (not shown). In certain implementations, each of the wordlines may be formed from and correspond to either a backside metal layer 230 or a frontside metal layer 240. While in the example perspective, the backside metal layers 230 are shown vertically, the frontside metal layers 240, 250 are shown horizontally, and the wordlines 122, 124, and 126 are each shown vertically, in other alternative implementations, such elements may be formed in different combinations of multi-planar or coplanar directions/orientations. Also depicted are various pull-up transistors (PU), pull-down transistors (PD) that in certain implementations may be arranged and/or coupled between a backside metal layer and a wordline. Further, in certain instances, passgate (PG) transistors may be arranged and/or coupled between a frontside metal layer and a wordline. Advantageously, in such implementations, in FIGS. 1 and 2, one wordline (e.g., a read or write wordline) can be a buried wordline and formed within the substrate.

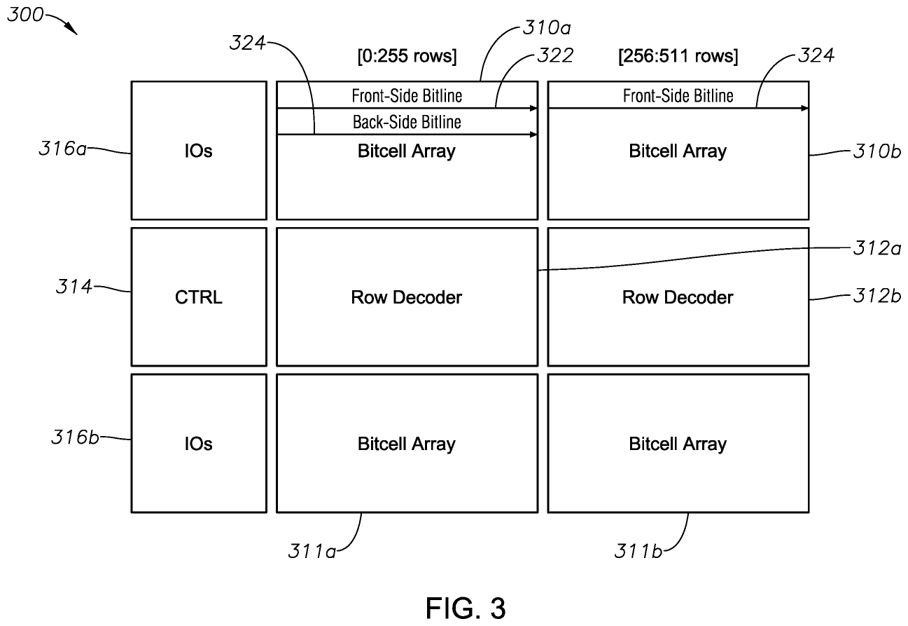

Referring to FIG. 3, an example portion of an integrated circuit 300 (e.g., a portion of a system-on-chip (SoC)) is shown. As illustrated, in certain implementations, the integrated circuit may include a memory macro unit 300 (e.g., including core array structure (e.g., a high density memory using backside and frontside bitlines). The memory macro unit 300 may include one or more bitcells of first and second bitcell arrays 310 (e.g., 310a, 310b) and one or more bitcells of third and fourth bitcell arrays 311 (e.g., 311a, 311b) (i.e., memory instances, core arrays, memory arrays) (e.g., single-port memory array); first and second word-line decoder blocks 312a, 312b (i.e., row decoders); and respective input/output (I/O) circuitry 316a, 316b for the first and second bitcell arrays 310, and third and fourth bitcell arrays 311. In various implementations, each of the I/O blocks 316 may include (not shown): sense amplifier circuitry, a pre-charge circuit, a column multiplexer, and input and output latches. In certain implementations, the first and second bitcell arrays 310 as well as the third and fourth bitcells arrays 311 may be coupled to the first and second word-line decoder blocks 312a, 312b. In certain implementations, the control circuitry 314 may be coupled to the first and second word-line decoder blocks 312a, 312b, the respective input/output (I/O) circuitry 316a, 316b, and the first and second bitcell arrays 310a, 310b, as well as the third and fourth bitcells arrays 311a, 311b.

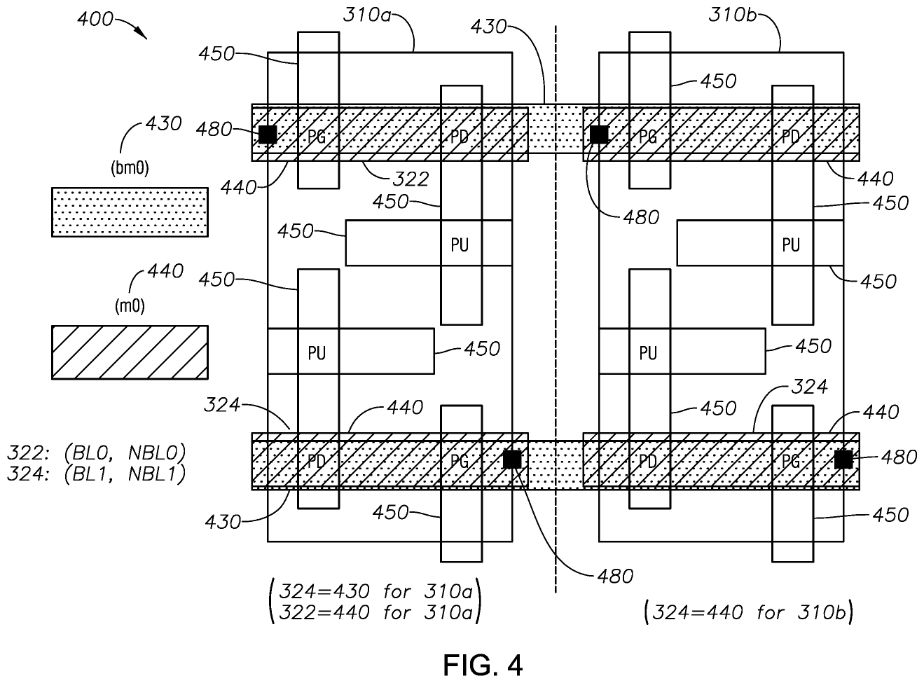

Also, in FIG. 3, first and second wires 322, 324 are shown. In one implementation: the first wire 322 is a first bitline (e.g., first complementary pair of bitlines (BL0, NBL0)) and the second wire 324 is a second bitline (e.g., second complementary pair of bitlines (BL1, NBL1)). In one example of such an implementation, the first wire 322 (e.g., the first bitline, first complementary pair of bitlines) may be configured to: be routed, formed from (e.g., correspond to), and/or at least partially positioned within (e.g., in certain cases: on, inside) a frontside metal layer (e.g., M0-M7) (as shown in greater detail in FIG. 4) for a first range (e.g., the first 255 rows) of bitcells of a first bitcell array 310a. In one example, the second wire 324 (e.g., the second bitline, second complementary pair of bitlines) may be configured to be routed, formed from (e.g., correspond to), and/or at least partially positioned on a backside metal layer (i.e., buried metal layer) for the same first range (e.g., the first 255 rows (e.g., 0:255 rows) of bitcells of the same first bitcell array 310a. In addition, the second wire 324 (i.e., the second bitline) may be: routed, formed from (e.g., correspond to), and/or at least partially positioned on a frontside metal layer for a second range (e.g., the second 255 rows, 256:511 rows) for a second bitcell array 310b. Hence, in such a scenario, the second bitline (i.e., second wire) 324 can be routed to “fly across” the first range of rows (e.g., 255 rows) of bitcells and then routed through a via, and sent “up” to the front side for the second range of rows of bitcells.

Advantageously, such a disposition, according to inventive aspects, utilizes both frontside and backside metal layers. In doing so, in one example, a high-density memory (e.g., a high-speed/high-performance memory) using backside and frontside bitlines may be implemented optimizing for area, power and timing in, e.g., L2 and L3 data. By using both frontside and backside metal for bitlines, the bitline range can be extended to 512 rows/bitline. Accordingly, a larger memory instance may be enabled such that there would be an increase in area and power.

In certain implementations, the control circuitry (CTRL) 314 may be configured to enable one or more critical signals on wiring (e.g., bitline) to control (e.g., selection for read/write of data, data placement during a write operation, data read during a read operation) the first and second bitcell arrays 310a, 310b and/or the third and fourth bitcell arrays 311a, 311b. In various examples, as described herein, a first wire (e.g., back-side bitline) of the wiring may be formed and disposed at least partially on a backside metal layer (or a buried metal layer). As may be appreciated, in the various implmentations as described herein, the critical control signals may be one or more data input signals (i.e., data input) (DB) or one or more write enable signals (WEN). Also, in certain implementations, the control circuitry (CTRL) 314 may be coupled to a ground rail or line (VSS) (not shown) that is coupled to the bitcell arrays 310, 311.

In certain implementations, one or more through silicon vias (TSVs) 480 may be positioned through the memory macro unit 300, 400. In certain implementations, the one or more TSVs may intersect the memory macro unit 300, 400 in a substantially perpendicular orientation (i.e., direction) to extend, in certain cases, vertically through a 3D memory stack. In certain aspects, the TSVs may be utilized by the SoC for the transferrance of the control signals routed through the frontside and backside metals and bitcells arrays of the memory macro unit.

Referring to FIG. 4, an example portion of an integrated circuit 400 (e.g., memory macro unit) corresponding to the integrated circuit 300 in FIG. 3 is shown. As depicted, in certain implementations, the integrated circuit 400 depicts the frontside and backside metal layers, first and second bitlines, shown within the example portion of the high-density single-port memory. As illustrated, each wiring (first and second bitlines 322, 324) is shown to be formed from, corresponding to, and at least partially disposed on different metal layers (e.g., metal levels). For instance, as illustrated, the first bitline (e.g., a bitline or a first complementary pair of bitlines BL0, NBL0) 322 corresponds to a frontside metal layer (e.g., shown as m0, but can be: m1-m7) and may be partially disposed within and/or upon the frontside metal layer 440 as well as to a first bitcell array 310a for a first range bitcells (e.g., first 255 rows). Likewise, the second bitline (e.g., a second bitline or a second complementary pair of bitlines BL1, NBL1) 324 corresponds to a backside metal layer (e.g., bm0) (e.g., formed within a substrate) and may be partially disposed within and/or upon the backside metal layer 430 (e.g., m0) 430 as well as to a first bitcell array 310a for the same first range of bitcells of the first bitcell array (e.g., first 255 rows). In addition, the second bitline (e.g., a second bitline or a second complementary pair of bitlines BL1, NBL1) 324 corresponds to a frontside metal layer (e.g., shown as m0, but can be: m1-m7) and may be partially disposed within and/or upon the frontside metal layer 440 for a second range (256:511 rows) of bitcells of a second bitcell array 310b or the first bitcell array 310a. While in the example perspective, the backside metal layer(s) 430 are shown horizontally, the frontside metal layer(s) 440 are shown horizontally, and the bitlines 322, 324 (e.g., first and second complementary pairs of bitlines (BL0, NBL0, BL1, NBL1)) are each shown horizontally (from this perspective), in other alternative implementations, such elements may be formed in different combinations of multi-planar or coplanar directions/orientations. Also depicted are various transistors 450 (e.g., pull-up transistors (PU), pull-down transistors (PD)) that in certain implementations may be arranged and/or coupled between a backside metal layer and a bitline (e.g., second bitline 324, second complementary pair of bitlines 324). Further, in certain instances, other transistors 450 (e.g., passgate (PG) transistors_may be arranged and/or coupled between a frontside metal layer and a bitline (e.g., second bitline 324, second complementary pair of bitlines 324). Advantageously, in such implementations, in FIGS. 3 and 4, one bitline (or complementary pair of bitlines BL1, NBL2) can be a buried bitline formed from the backside metal layer within the substrate.

In some implementations, the control circuitry (CTRL) 314 may include one or more precharge lines (not shown) that are coupled to the first and second bitlines 322, 324 (e.g., first complementary bitlines (BL0, NBL0) and the second complementary bitlines (BL1, NBL1)). Also, in some instances, the control circuitry (CTRL) 314 may use the precharge lines to precharge at least one of the first and second bitlines. Also, in some cases, the precharge lines may be formed as frontside conductive rails or lines in the frontside metal (FM) layers.

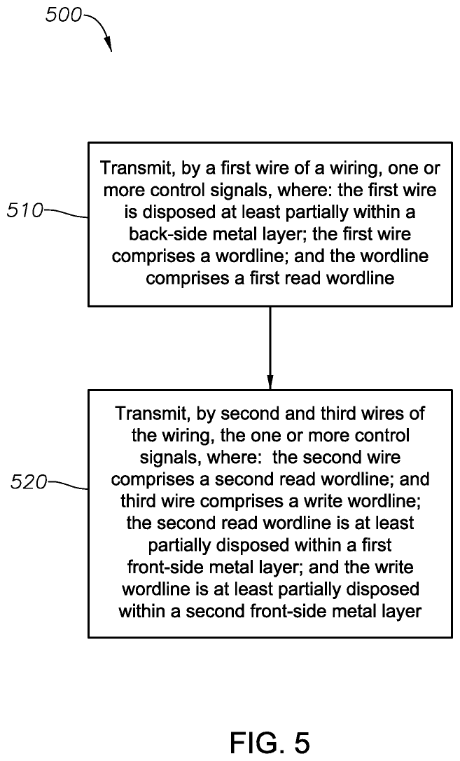

Referring to FIG. 5, a flowchart of an example operational method 500 (i.e., procedure) to is shown. Advantageously, in various implementations, the method 500 may optimize for better memory performance and memory timing. The method 500 may be implemented with reference to circuit implementations as shown in FIGS. 1-2.

At block 510, the method includes: transmitting, by a first wire of a wiring, one or more control signals, where: the first wire is disposed at least partially within a back-side metal layer; the first wire comprises a wordline; and the wordline comprises a first read wordline. For instance, with reference to various implementations as described in FIGS. 1-2, a control block 114 may be configured to transmit control signals (WEN, DB) upon and to enable the first wire (e.g., a first read wordline (RWL0)), where the first wire is disposed at least partially within a back-side metal layer (e.g., bm0).

At block 520, the method includes: transmitting, by second and third wires of the wiring, the one or more control signals, where: the second wire comprises a second read wordline; and third wire comprises a write wordline; the second read wordline is at least partially disposed within a first frontside metal layer; and the write wordline is at least partially disposed within a second frontside metal layer. For instance, with reference to various implementations as described in FIGS. 1-2, a control block 114 may be configured to transmit control signals upon and to enable the second and third wires (e.g., a second read wordline (RWL1), a write wordline (WWL0)) at least partially disposed on different front side metal layers (e.g., m3 and m1), respectively.

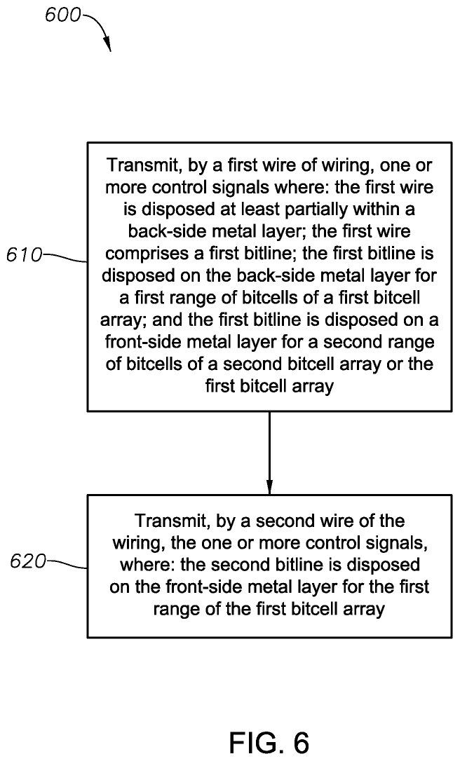

Referring to FIG. 6, a flowchart of an example operational method 600 (i.e., procedure) to is shown. Advantageously, in various implementations, the method 600 may optimize for area, power and timing (e.g., L2 and L3 data). The method 600 may be implemented with reference to circuit implementations as shown in FIGS. 3-4.

At block 610, the method includes: transmitting, by a first wire of wiring, one or more control signals where: the first wire is disposed at least partially within a back-side metal layer; the first wire comprises a first bitline; the first bitline is disposed on the back-side metal layer for a first range of bitcells of a first bitcell array; and the first bitline is disposed on a frontside metal layer for a second range of bitcells of a second bitcell array or the first bitcell array. For instance, with reference to various implementations as described in FIGS. 3-4, a control block 314 may be configured to transmit control signals upon and to enable a first wire (e.g., second bitline 324, second complementary pair of bitlines BL1, NBL1) that is disposed at least partially within a back-side metal layer (e.g., bm0) for a first range of bitcells (e.g., 0:255 rows) of a first bitcell array (e.g., bitcell array 310a), and is disposed on a frontside metal layer (e.g., m0) for a second range of bitcells (e.g., 256:511 rows) of a second bitcell array (e.g., bitcell array 310b) or the first bitcell array (e.g., bitcell array 310a).

At block 620, the method includes: transmitting, by a second wire of the wiring, the one or more control signals, where: the second bitline is disposed on the frontside metal layer for the first range of the first bitcell array. For instance, with reference to various implementations as described in FIGS. 3-4, a control block 314 may be configured to transmit control signals upon and to enable a second wire (e.g., first bitline 322, first complementary pair of bitlines BL0, NBL0) that is disposed on the frontside metal layer (e.g., m0) for the first range of bitcells (e.g., 0:255 rows) of the first bitcell array (e.g., bitcell array 310a).

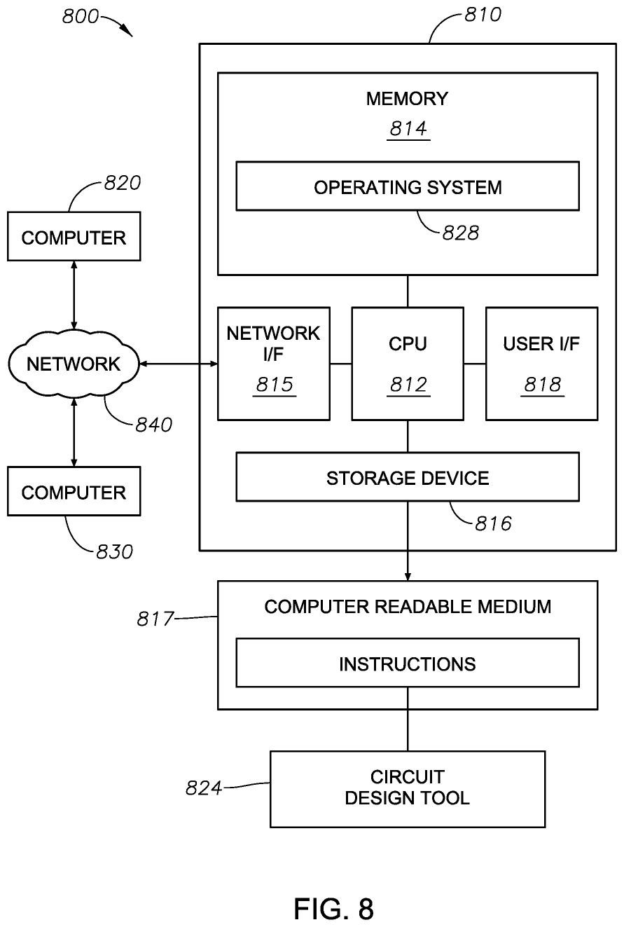

Also, according to other aspects of the operational methods, an output may be generated based on the operational dispositions. For example, with reference to various implementations as described in FIGS. 1-6, an output (i.e., an integrated circuit design) (e.g., a memory architecture, multi-threshold offerings for memory compilers) may be generated based on the determined positioning of the wiring (e.g., wordline(s) and bitline(s)) positionings. In some implementations, the circuit design tool 824 (as described with reference to FIG. 8) may allow users to input certain values, and generate memory macro unit(s).

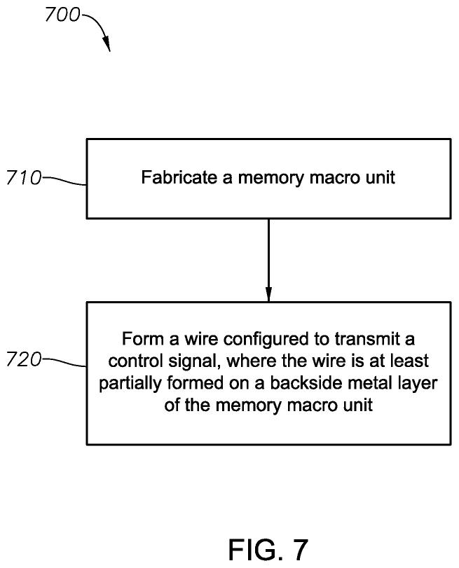

Referring to FIG. 7, a flowchart of an example formation method 700 (i.e., procedure) to for backside wire integration is shown. Advantageously, in various implementations, the method 700 depicts the fabrication method steps for a three-dimensional semiconductor stack. The method 700 may be implemented with reference to circuit implementations as shown in FIGS. 1-4.

At block 710, the method includes fabricating a memory macro unit. For instance, with reference to various implementations as described in FIGS. 1-4, a memory macro unit (100, 200, 300, 400) may be fabricated from a multi-step sequence of photolithographic and chemical processing steps (such as surface passivation, thermal oxidation, planar diffusion, and junction isolation) during which electric circuits are gradually created on a wafer made of semiconducting material.

At block 720, the method includes: forming a wire configured to transmit a control signal, where the wire is at least partially formed on a backside metal layer of the memory macro unit. For instance, with reference to various implementations as described in FIGS. 1-4, a wire (e.g., wordline(s) or bitline(s)) may be formed by etching through conductive loops (e.g., concentric) conductive strip) on a backside metal later (i.e., a buried metal layer) of the memory macro unit. As may be appreciated, etching is a process used to remove layers or slices of a material and can employ, in various implmentations, electrochemical electrolysis, chemical corrosion, and even mechanical polishing arts.

In various implementations, the wire fabrication may include: fabricating a back-end-of-line (BEOL) wiring to be coupled to the wiring, and bonding and at least partially through the memory macro unit (100, 200, 300, 400). Also, according to other aspects of the operational method, the wiring (e.g., wordline(s) or bitline(s) may be revealed by removing a layer from a back portion of a substrate (e.g., semiconductor wafer). In other aspects, the wiring may be adjoined to a back-end-of-line (BEOL) stack, where the BEOL stack can be coupled to a face-to-face semiconductor wafer bond.

In various implementations, bitcell architectures described herein may provide for fabricating memory circuitry with various integrated circuit (IC) components that may be arranged and/or coupled together as an assemblage or some combination of parts that provide for physical circuit designs, structures and/or applications. In some instances, a method of designing, providing and fabricating the bitcell architectures as an integrated device may involve use of circuit components and/or related structures described herein to implement various techniques associated therewith. Also, the bitcell architectures may be integrated with various circuitry and related components on a single chip, and further, the bitcell architectures may be implemented in various embedded devices for automotive, mobile, computer, server and/or Internet-of-Things (IoT) based applications, including remote sensor nodes.

FIG. 8 illustrates example hardware components in the computer system 800 that may be used to determine an optimized wiring positioning and to generate an integrated circuit design/memory architecture output. In certain implementations, the example computer system 800 (e.g., networked computer system and/or server) may include circuit design tool 824 and execute software based on the procedure as described with reference to the methods 500, 600, and 700 in FIGS. 5-7. In certain implementations, the circuit design tool 824 may be included as a feature of an existing memory compiler software program allowing users to input various pitches, and generate memory macros that either fit within a predetermined pitch or provide a feed-through option (i.e., an option allowing for at least a partial coupling or disposition through (i.e., at least partially within) various elements of the memory macro unit(s)).

The circuit design tool 824 may provide generated computer-aided physical layout designs for memory architecture. The procedure 800 may be stored as program code as instructions 817 in the computer readable medium of the storage device 816 (or alternatively, in memory 814) that may be executed by the computer 810, or networked computers 820, 830, other networked electronic devices (not shown) or a combination thereof. In certain implementations, each of the computers 810, 820, 830 may be any type of computer, computer system, or other programmable electronic device. Further, each of the computers 810, 820, 830 may be implemented using one or more networked computers, e.g., in a cluster or other distributed computing system.

In certain implementations, the system 800 may be used with semiconductor integrated circuit (IC) designs that contain all standard cells, all blocks or a mixture of standard cells and blocks. In a particular example implementation, the system 800 may include in its database structures: a collection of cell libraries, one or more technology files, a plurality of cell library format files, a set of top design format files, one or more Open Artwork System Interchange Standard (OASIS/OASIS.MASK) files, and/or at least one EDIF file. The database of the system 800 may be stored in one or more of memory 814 or storage devices 816 of computer 810 or in networked computers 820, 820.

The system 800 may perform the following functions automatically, with variable user input: determination of read current requirements/thresholds, determination of leakage current requirements/thresholds, identification of logic designs (i.e., periphery circuit designs (i.e., logic threshold voltages, threshold voltage implant layers)), determination of a desired threshold voltage-combination, determination of minimum voltage assist requirements, identification of bit-cell types, determination of memory specific optimization modes (memory optimization mode), floor-planning, including generation of cell regions sufficient to place all standard cells; standard cell placement; power and ground net routing; global routing; detail routing and pad routing. In some instances, such functions may be performed substantially via user input control. Additionally, such functions can be used in conjunction with the manual capabilities of the system 800 to produce the target results that are required by a designer. In certain implementations, the system 800 may also provide for the capability to manually perform functions such as: cell region creation, block placement, pad and cell placement (before and after automatic placement), net routing before and after automatic routing and layout editing. Moreover, verification functions included in the system 800 may be used to determine the integrity of a design after, for example, manual editing, design rule checking (DRC) and layout versus schematic comparison (LVS).

In one implementation, the computer 800 includes a central processing unit (CPU) 812 having at least one hardware-based processor coupled to a memory 814. The memory 814 may represent random access memory (RAM) devices of main storage of the computer 810, supplemental levels of memory (e.g., cache memories, non-volatile or backup memories (e.g., programmable or flash memories)), read-only memories, or combinations thereof. In addition to the memory 814, the computer system 800 may include other memory located elsewhere in the computer 810, such as cache memory in the CPU 812, as well as any storage capacity used as a virtual memory (e.g., as stored on a storage device 816 or on another computer coupled to the computer 810).

The computer 810 may further be configured to communicate information externally. To interface with a user or operator (e.g., a circuit design engineer), the computer 810 may include a user interface (I/F) 818 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 810 may include a network interface (I/F) 815 which may be coupled to one or more networks 840 (e.g., a wireless network) to enable communication of information with other computers and electronic devices. The computer 860 may include analog and/or digital interfaces between the CPU 812 and each of the components 814, 815, 816, and 818. Further, other non-limiting hardware environments may be used within the context of example implementations.

The computer 810 may operate under the control of an operating system 826 and may execute or otherwise rely upon various computer software applications, components, programs, objects, modules, data structures, etc. (such as the programs associated with the procedure 700 and the method 700 and related software). The operating system 828 may be stored in the memory 814. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 826 in the example of FIG. 8 is shown in the memory 814, but components of the aforementioned software may also, or in addition, be stored at non-volatile memory (e.g., on storage device 816 (data storage) and/or the non-volatile memory (not shown). Moreover, various applications, components, programs, objects, modules, etc. may also execute on one or more processors in another computer coupled to the computer 810 via the network 840 (e.g., in a distributed or client-server computing environment) where the processing to implement the functions of a computer program may be allocated to multiple computers 820, 830 over the network 840.

In example implementations, circuit macro diagrams have been provided in FIGS. 1-4, whose redundant description has not been duplicated in the related description of analogous circuit macro diagrams. It is expressly incorporated that the same cell layout diagrams with identical symbols and/or reference numerals are included in each of embodiments based on its corresponding figure(s).

Although one or more of FIGS. 1-8 may illustrate systems, apparatuses, or methods according to the teachings of the disclosure, the disclosure is not limited to these illustrated systems, apparatuses, or methods. One or more functions or components of any of FIGS. 1-8 as illustrated or described herein may be combined with one or more other portions of another of FIGS. 1-8. Accordingly, no single implementation described herein should be construed as limiting and implementations of the disclosure may be suitably combined without departing from the teachings of the disclosure.

Aspects of the present disclosure may be incorporated in a system, a method, and/or a computer program product. The computer program product may include a computer-readable storage medium (or media) having computer-readable program instructions thereon for causing a processor to carry out aspects of the present disclosure. The computer-readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire. For example, the memory 814, the storage device 816, or both, may include tangible, non-transitory computer-readable media or storage devices.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. An integrated circuit comprising:
a memory macro unit comprising:
one or more bitcells of one or more bitcell arrays, wherein a wordline or a bitline is at least partially disposed within a backside metal layer of the memory macro unit.

2. The integrated circuit of claim 1, wherein the wordline or the bitlines is coupled to the one or more bitcells of the one or more bitcell arrays.

3. The integrated circuit of claim 1, wherein the memory macro unit further comprises:
control circuitry configured to enable the wordline or the bitline to control the one or more bitcells of the one or more bitcell arrays.

4. The integrated circuit of claim 3, wherein the wordline comprises a first read wordline, and wherein the control circuitry is configured to enable the first read wordline.

5. The integrated circuit of claim 4, wherein:
a second read wordline is at least partially disposed on a first frontside metal layer; and
a first write wordline is at least partially disposed on a second frontside metal layer.

6. The integrated circuit of claim 5, wherein the control circuitry is configured to enable the second read wordline and the first write wordline on the respective first and second frontside metal layers.

7. The integrated circuit of claim 3, wherein the bitline comprises a first bitline, and wherein the control circuitry is configured to enable the first bitline.

8. The integrated circuit of claim 7, wherein:
the first bitline is disposed on the back-side metal layer for a first range of bitcells of a first bitcell array of the one or more bitcell arrays; and
the first bitline is disposed on a frontside metal layer for a second range of bitcells of second bitcell array of the one or more bitcell arrays or the first bitcell array.

9. The integrated circuit of claim 8, wherein:
a second bitline is disposed on the frontside metal for the first range of the one bitcells of the first bitcell array; and
the control circuitry is configured to enable the second bitline.

10. The integrated circuit of claim 8, further comprising:
a through silicon via (TSV) configured to route the first bitline from the back-side metal layer to the frontside metal layer.

11. The integrated circuit of claim 1, further comprising:
one or more word-line decoder blocks; and
respective input/output (I/O) circuitry for each of the one or more bitcell arrays, wherein:
the one or more bitcell arrays are coupled to the one or more word-line decoder blocks; and
the control circuitry is coupled to the one or more word-line decoder blocks, the respective input/output (I/O) circuitry, and the one or more bitcell arrays.

12. The integrated circuit of claim 1, wherein the backside metal layer is coupled to the one or more bitcell arrays.

13. A method comprising:
transmitting, by a first wire of a wiring, one or more control signals, wherein the first wire is disposed at least partially within a back-side metal layer.

14. The method of claim 13, wherein the wiring is configured to transmit the one or more control signals from a control block to one or more bitcells of one or more bitcells arrays.

15. The method of claim 14, wherein the first wire comprises a wordline or a bitline.

16. The method of claim 15, wherein:
the first wire comprises the wordline;
the wordline comprises a first read wordline, and wherein the control circuitry is configured to enable the first read wordline.

17. The method of claim 16, further comprising:
transmitting, by second and third wires of the wiring, the one or more control signals, wherein:
the second wire comprises a second read wordline and third wire comprises a write wordline;
the second read wordline is at least partially disposed within a first frontside metal layer;
the write wordline is at least partially disposed within a second frontside metal layer; and
the control circuitry is configured to enable the second read wordline and the write wordline on the respective first and second frontside metal layers to control the one or more bitcells of one or more bitcells arrays.

18. The method of claim 15, wherein:
the bitline comprises a first bitline, and wherein the control circuitry is configured to enable the first bitline;
the first bitline is disposed on the backside metal layer for a first range of bitcells of a first bitcell array of the one or more bitcell arrays; and
the first bitline is disposed on a frontside metal layer for a second range of bitcells of second bitcell array of the one or more bitcell arrays or the first bitcell array.

19. The method of claim 18, further comprising:
transmitting, by a second wire of the wiring, the one or more control signals, wherein:
the second bitline is disposed on the frontside metal layer for the first range of the one bitcells of the first bitcell array; and
the control circuitry is configured to enable the second bitline.

20. An integrated circuit comprising:
a memory macro unit comprising: one or more bitcells of one or more bitcell arrays, wherein at least a partial portion of a backside metal layer of the memory macro unit is formed as a wordline or a bitline.
